(19) United States
(12) Patent Application Publication
(10) Pub. No.: US 2009/0057133 A1
(43) Pub. Date: Mar. 5, 2009

(54) Method and Apparatus for Reactive Solid-Gas Plasma Deposition

(76) Inventor: Vladimir Kouznetsov, Nynashamn (SE)

Correspondence Address: NIXON & VANDERHYE, PC, 901 NORTH GLEBE ROAD, 11TH FLOOR, ARLINGTON, VA, 22203, US

(21) Appl. No.: 10/580,406

(22) PCT Filed: Nov. 24, 2004
(86) PCT No.: PCT/SE04/01742

§ 371 Date: Sep. 23, 2008

(30) Foreign Application Priority Data
Nov. 24, 2003 (SE) 0303136-6

(51) Int. Cl. C23C 14/35

(52) U.S. Cl. 204/192.12; 204/298.19; 204/298.13; 204/298.02

(57) ABSTRACT

A device for magnetically enhanced sputtering and plasma deposition includes a plasma source unit and a work piece processing unit in which an anode space and a processing chamber are located in direct communication with each other. Sputtering and reactive gases are provided through an inlet of the processing chamber holding the work piece. Pulsed electric discharges are produced between the magnetron sputtering cathode and the anode, including walls of the anode space. A stationary magnetic mirror trap is provided in the combined vessel by an anode coil surrounding the anode space and another coil mounted at the processing chamber remote from the cathode. A plasma can then flow into the processing chamber suitable for reactive deposition on three-dimensional and large work pieces. A chemisorption filter including filter plates is arranged in the anode space for preventing penetration of the reactive gas into the region at the cathode. The other coil can be included in a plasma source similar to the first one, both plasma sources connected to the same work piece processing unit.

### TECHNICAL FIELD

The present invention relates methods and apparatus for reactive solid-gas plasma deposition, such as for coating work pieces with metals oxides, and in particular a magnetic solid-gas plasma reactor for deposition of electrically insulating substances such as oxides, e.g. metal oxides.

### BACKGROUND

For coating work pieces by means of partially ionized metal vapor and gas plasma magnetic plasma reactors are widely used.

In W.-D. Munz et al., “An all-round performer in the physical vapour deposition Laboratory”, Surface and Coating Technology, Vol. 58, 1993, pp. 205-212, a magnetic plasma reactor including two unbalanced magnetrons is disclosed. For the same polarities of the magnetrons used, the plasma zones positioned in front of targets in effect repel one another, whereas for opposite polarities the plasma remains largely concentrated and self-enclosed within the space between the cathodes, and thereby high plasma densities or bias current densities can be attained.

In U.S. Pat. No. 5,556,519 for D. Teer, published European patent application 0521045 and published British patent application 2258343, a variety of magnetic plasma reactors arranged by two, three, four or six coupled magnetrons placed symmetrically around an axis are described. In this magnetic arrangement the magnetron magnetic field is used both for vapor and plasma production and for plasma confinement.

In U.S. Pat. No. 5,196,105 for H. Schussler et al. a magnetic plasma reactor is disclosed that is arranged within a vacuum chamber on a substrate holder which is situated at least partially in a coating range on the both sides of which magnetron cathodes including magnet systems of permanent magnets having outside poles and inside poles are arranged, wherein the polarity of the magnet systems of the magnetron cathodes is such that poles of opposed polarity are located opposite one another on both sides of the coating range; and on opposite sides of the coating range at least one magnet coil is located, and the oppositely situated magnet coils being connectable to a power source in such a manner that the fields of the magnet coils together make up a closed magnetic field, and that the polarity of the outside poles of the permanent magnet systems and of the magnet coils is the same.

W.-D. Munz et al. see the article cited above, has described a magnetic plasma reactor that is used in an HTC 625 Multilab coater. Two coupled electromagnetic coils are provided at the reactor. Coils are powered by a DC power supply. The plasma injectors for injecting into the reactor are or two magnetrons sputtering cathodes or two controlled arc cathodes. Transformation of magnetron sputtering cathodes in steered arc cathodes is achieved by removing the permanent magnetic system from the target for decreasing the magnetic field strength at the sputtered surface of the target. Using such a reactor the substrate current can be increased by a factor of 8. The work piece is positioned inside the plasma reactor.

In W.-D. Munz et al., “A new method for hard coatings: ABS™ (ark bond sputtering)”, Surface and Coating Technology, Vol. 50, 1992, pp. 169-178, a magnetic plasma reactor arranged by four coupled rectangular electromagnets that are positioned symmetrically around a common axis is disclosed. The direction of magnetic field force lines in each electromagnet is opposite to the direction of force lines in the two neighboring electromagnets. Electromagnets are powered from DC power supplies. The injectors of metal vapor and plasma are four magnetron-sputtering cathodes or four steered arc cathodes. Cathodes are placed inside the electromagnets. Transformation of magnetron sputtering cathodes in steered arc cathodes is accomplished by removing the permanent magnetic system from target for decreasing the magnetic field strength at the target sputtered surface. The work pieces are placed inside the magnetic reactor. These magnetic arrangements are used in HAUZER coating machines of HTC1000-4ABS™ type, see the cited article by W.-D. Munz et al., “A new method for hard coatings: ABS™ (ark bond sputtering)”.

In U.S. Pat. No. 6,383,565 for D. P. Monaghan a magnetic plasma reactor is disclosed in which the ion current density is carefully controlled to improve coating. This control enhanced the versatility and enlarges the range of deposition conditions, which can be achieved within a single apparatus, so that coatings with very different properties can be deposited in the same equipment. The deposition apparatus includes a vacuum chamber, at last one coating means or ionization source disposed at or about the periphery of a coating zone. One or more internal magnetic means are positioned such that the magnetic field lines generally extend across the coating zone and means are provided for altering the strength or position of the magnetic field lines to aid in plasma confinement.

In published U.S. patent application 2002/019,5336 for D. A. Glocker a magnetic plasma reactor is disclosed that comprises an array of unbalanced magnetrons arranged around a centrally located space for sputtering coatings of material from target electrodes in the magnetrons onto a substrate disposed in the space. The electrodes are powered in pairs by an alternating voltage and current source. The unbalanced magnetrons, which may be planar, cylindrical, or conical, are located at opposite sides of the substrate space or are located adjacent to each other on the same side of the substrate space. The magnetrons have identical magnetic polarity. A positive plasma potential produced by the AC driver prevents electrons from escaping to ground along unclosed magnetic field lines, increasing plasma density in the background working gas and thereby improving the quality of coatings deposited on the substrate.

All the magnetic plasma reactors including magnetrons as injectors as mentioned above are used for deposition of conductive films, primarily carbon or metal films, or of films of metal nitrides. The work pieces/substrates are placed inside the magnetic plasma reactors. These reactors cannot be used for reactive sputtering in an oxygen atmosphere and for metal oxide deposition.

As can be observed, the magnetron sputtering cathodes are the essential parts of magnetic plasma reactors. In all reactors discussed above, magnetrons of two types are used. These are balanced and unbalanced magnetrons. Magnetrons are operating in the DC regime at a relatively low power. For example, in the HTC 625 Multilab coater including rectangular targets having dimensions of 400×125 mm installed as the standard option, the operating power is 6.5 kW, see the cited article by W.-D. Munz et al., “An all-round performer in physical vapour deposition laboratory”. In this case the cathodes operate mainly as a metal vapor source and the magnetic reactors are used for increasing the influence of the very low-density plasma on the deposition process.

V. Kouznetsov, see the published International patent application WO 01/98553, has described another type of magnetic plasma reactor. Two coaxial electromagnetic coils provide the magnetic field of the reactor. Coils are located outside an extended anode tube that in the preferred case is elongated, e.g. having a length of about twice its diameter, but it can generally have a length of 0.5-3 diameters. The coils are electrically separated from each other and are placed on some distance of each other. Independent DC power supplies deliver power to the coils. One of the coils is much longer then the other one. As a plasma injector into the magnetic reactor a conventional balanced magnetron sputtering cathode is used. The cathode is placed at one end of the anode tube near the long electromagnetic coil. At the end of the anode tube a shielding plate is located. This plate has an opening of a diameter smaller than the inner diameter of the anode tube. The anode tube is connected to a vessel or space where the substrate is positioned. The substrate is located outside the magnetic plasma reactor.

According to the International patent application, the magnetron sputtering cathode operates in the high power pulsed regime, see U.S. Pat. No. 6,296,742 B1, this regime allowing that high density metal and gas plasmas are produced. Such a plasma reactor is in particular used for depositing nonconductive metal oxide films. Metal films and metal nitrides films also can be deposited. On the inner surfaces of the anode tube and of the shielding plate target material is deposited, this deposited material used as a getter for oxygen and thereby the oxygen partial pressure near the target is strongly reduced. The inner surfaces of the anode and of the shielding plate thus provide a getter pump for the reactive gas that in this case is oxygen.

Getter pumps are widely used in vacuum technology, see U. R. Bance, “Development of a diode/triode (D/T) ion pump”, Vacuum, Vol. 40, No. 5, 1990, pp. 457-460, T. S. Chou, J. Vac. Sci. Technol., “Design study of distributed ion pumps”, A5(6) November/December 1987, pp. 3446-3452; Y. Suetsugu, “An improved empirical formula for pumping speeds of ion pumps in the high magnetic field”, Vacuum, Vol. 42, No. 12, 1991, pp. 761-767; Y. Suetsugu, “Design study of new distributed ion pumps for the TRISTAN accumulation ring”, Vacuum, Vol. 2, Nos. 10/11, 1991, pp. 625-634. In getter pumps the anode is assembled as a large surface on which titanium films are deposited. The titanium vapor that is used for the film deposition is produced by high voltage sputtering of a Ti cathode. The specific feature of this method of film deposition is that only Ti vapor is used. That is the principal difference of this method from the method described in the cited International patent application WO 01/98553. According to this patent application both metal vapor and plasma are used. The metal vapor is used for providing getter films for oxygen chemisorption. The plasma is guided and directed by the magnetic field onto the work piece for thin film deposition.

There is another method of metal oxide film deposition, see the published European patent application 1070767. This method is used for deposition of transparent, conductive-metal oxides films, TCO (Transparent Conductive Oxide), such as ITO (Indium-Tin Oxide), SnO₂ or ZnO. In this method for deposition of metal oxide films on large surfaces and better target utilization a mobile magnet system is used. The magnet for creating the magnetic field is reciprocating across the film deposition region. For similar goals a mobile magnet system is used also in the methods described in U.S. Pat. Nos. 5,328,585 and 5,873,989 and the published European patent application 1120811.

In U.S. Pat. No. 6,077,403 for Kobayashi et al. a sputtering method and device are disclosed, the sputtering device including a single chamber. High frequency electric power (13.56 MHz) is supplied to the target. A supplemental electrode 6 surrounds the flight path of sputtered particles between the target and the substrate. First and second magnets 71, 72 are provided, the first magnets surrounding the flight path and the second ones placed behind the substrate. The magnetic field produced assists in e.g. extraction of electrons or ions from the created plasma. A similar sputtering device is disclosed in U.S. Pat. No. 6,444,099 for Sasaki et al.

In U.S. Pat. No. 5,196,105 a system for coating substrates is disclosed including at least two magnetron sputtering cathodes having surfaces being walls of the same vacuum chamber. Magnet coils surround the cathodes, the fields of the coils combining to form a continuous, closed magnetic field.

### SUMMARY

It is an object of present invention to provide methods and devices allowing deposition of films, in particular metal oxide films, onto three dimensional work pieces using pulsed magnetron sputtering.

It is another object of present invention to provide methods and devices allowing deposition of metal oxide films onto relatively large work pieces using pulsed magnetron sputtering.

A problem, which the invention intends to solve, is how to efficiently fill a magnetic plasma reactor having large dimensions with metal and oxygen plasmas without formation of dielectric layers on the electrodes between which magnetron discharges occur.

It was found that in the magnetic plasma reactor according to the cited International patent application WO 01/98553 the deposition rate drastically decreases at a distance of about few centimeters outside the outlet opening of the plasma source. Therefore this kind of magnetic plasma reactor can be efficiently used only for thin film deposition on two dimensional work pieces placed near the plasma source outlet.

It was found that in order to obtain metal and gas plasmas in regions remote of the outlet opening of the plasma source it is necessary to use as a minimum one more electromagnetic coil located at a distance of the plasma source outlet, i.e. remotely of this outlet. In this configuration of a magnetic plasma reactor the reactor can be split in two parts: a plasma source unit as in the cited International patent application WO 01/98553, also called only plasma source, and a work piece processing unit, also called only processing unit or processor, the plasma source unit including a magnetron sputtering cathode and a reactive gas chemisorption filter unit, ChemFilt or CF, also called or only the filter or the filter unit. The work piece processing unit has to be directly connected to the plasma source unit so that the inner space, called the anode space, in the plasma source unit is in direct communication with the inner space, called the processing chamber, in the work piece processing unit, these two inner spaces forming a gas and vacuum tight space. An extra coil or solenoid is advantageously placed externally of the work piece processing unit, preferably axially symmetric to coils of the plasma source unit. The arrangement of the plasma source unit and the work piece processing unit, taken sequentially when passing from the cathode, is as follows: the magnetron sputtering cathode, the CF unit that also works as the anode, the work piece processing unit containing the work piece, and finally the additional electromagnetic coil that is mounted externally of the processing unit. The direction of the CF magnetic field is opposite to the direction of magnetron magnetic field at the axis of the installation.

In another configuration the magnetic plasma reactor includes two magnetrons, two chemisorption filters and a common work piece processing unit. The work piece processing unit is placed between the two CF units. The whole installation is vacuum sealed. All parts can be assembled along the same geometrical axis or the magnetron and the CFs can be assembled along two axes that are located in an angle in relation to each other. The direction of the magnetic field produced by the CF units is opposite to the direction of magnetron magnetic field at the axis of the respective magnetron sputtering cathode.

In still another configuration of the magnetic plasma reactor four magnetrons and four CF units are connected to the work piece processing unit at right angles to each other. In all units the direction of the CF unit magnetic field is opposite to the direction of the magnetron magnetic field at the axis of the respective magnetron.

As was mentioned above, a chemisorption filter can be used for protecting the magnetron sputtering cathode from oxidation during the reactive sputtering deposition process. The chemisorption filter can e.g. be linear or cylindrical. The dimensions, the design and the operational regime of the CFs are main reactor issues strongly influencing the deposition efficiency.

The magnetron sputtering cathode is used as a source of getter material for the operation of the associated chemisorption filter and also as a source of metal material for the plasma performing the work piece coating. It is obvious that the efficiency of the sputtering deposition in the chemisorption filter has to be higher than normal to meet the two requirements: efficient metal vapor production, i.e. getter production, and efficient metal plasma production. Conventional balanced and unbalanced magnetron sputtering cathodes operating in the pulsed regime according to the cited U.S. Pat. No. 6,296,742 can have an insufficient efficiency from this point of view. Moreover, increased magnetron operational power is mostly required for efficient metal plasma production resulting in a strong decrease of the energetic efficiency of metal vapor production. It can be said that attempts to increase the metal plasma portion results in a decrease of both metal vapor and plasma portions because the metal plasma is produced by partial ionization of metal vapor. Generally speaking, it can also be said that conventional magnetrons operating in the powerful pulsed regime do not allow that efficient magnetic metal gas plasma reactor operation is obtained.

It was found that a solution to this problem is to provide a specially designed permanent magnetic system below the sputtering target surface. This system can be presented as more than one independent magnetron that uses the same target. In practice it looks as follows. It is a well known fact that a conventional magnetron produces a narrow erosion track at the target surface. More than one magnetron assembly has to produce more than one erosion track. In particular for a circular planar magnetron it means that at the sputtered target surface there will be as a minimum two concentric erosion tracks. Increasing the number of erosion tracks results in increasing the amount of metal vapor produced by a corresponding increase of discharge power. Increasing the discharge power according to the cited U.S. Pat. No. 6,296,742 results in a good efficiency of gas and vapor ionization.

In terms of magnetic field topography it means that at the sputtering target surface the magnitude of the magnetic field component parallel to the surface has more than one maximum when passing from the center of the sputtering target to the external edge thereof. In terms of magnetic force lines it means that force lines near the sputtered surface have to cross the target surface as a minimum three times on the way from the center of the sputtering surface to the external edge thereof. A corresponding permanent magnetic system for such field production is a multi-polar magnetic system including a sequence of axially symmetric concentric magnets, each having a circular annular shape for circular magnetrons or a rectangular frame-like shape for rectangular magnetrons. The sequence of magnets can have reverse polarities of neighboring magnets, i.e. have alternating polarities, or all magnets can have the same polarity, i.e. have all their poles of the same polarity e.g. directed towards the sputtering surface.

Other positive features of the magnetrons as described above operating in the high power pulsed regime include a high rate of target utilization and a significantly reduced probability of the thermal arc formation phenomenon.

Magnetrons more suitable than the conventional type, that usually has only one erosion track, for the reactors described herein are e.g. disclosed in the published International patent application WO 01/77405. The rate of target utilization is increased by adding an intermediate magnetic pole. A similar effect is described by the company Gencoa, see the Internet site www.gencoa.com, section “Accessories”, “Retrofit magnetic array”. In these magnetrons magnetic force lines are bent near the cathode surface. For a conical cathode shape a similar magnetic field structure is disclosed in U.S. Pat. No. 6,458,252. A multipolar magnetic system is described as well in U.S. Pat. No. 5,306,407.

In other words, adding one more erosion track results in a more homogeneous discharge current distribution. Another method of achieving a uniform current distribution across target surface is described at the Internet site www.angstromsciences.com. It is based on a specific “sharpening” of permanent magnets arranged as the magnetron magnetic system. A similar effect is achieved by the company Gencoa, see the Internet site www.gencoa.com, section “full face erosion”, disclosing an alternative way to increase the energetic efficiency of the high power pulsed magnetron sputtering technique. This method as well is based on a more uniform discharge current distribution over the target surface.

Similar to the method disclosed at www.angstomsciences.com a method of increasing target rate utilization is disclosed in the cited U.S. Pat. No. 6,296,742 for Koumetsov. Magnetic field lines are strongly concentrated at the center pole and at the peripheral pole, see FIGS. 3 and 5b.

It can generally be said that the cited International patent application WO 01/77405, the cited U.S. Pat. Nos. 6,458,252, 5,306,407 and 6,296,742, and also U.S. Pat. No. 6,432,285 and the published International patent application WO 03/041113 are directed to methods for increasing target rate utilization. However, it was found that the same principles can be used for increasing the energetic efficiency of the production of vapor from solid/s/ by magnetron sputtering cathodes operating in the high power pulsed regime.

The magnetrons disclosed in the cited patents are described as powered by DC or low power pulsed or RF power supplies. It was found that if these magnetrons are powered by high power, low duty cycle pulsers, according to the cited U.S. Pat. No. 6,296,742, or are operating in a high power, low duty cycle pulsed regime according this U.S. patent, they have the additional advantage of an increased energetic efficiency at high discharge currents and another advantage that the probability of arcing is strongly reduced.

Thus, a combination of the two known phenomena gives two new unknown phenomena, a high energetic efficiency and a significantly reduced probability of the thermal arc formation.

In the method described in the cited U.S. Pat. No. 6,296,742 the pulsed discharge power is very high and therefore the use of this method for deposition of TCO on large surface thin film solar battery chips is problematic. A typical example is that solar batteries installed on a roof of a house and the like are required to include chips having a large area to provide a larger power efficiency at a low cost. The solution to this problem is to use reciprocally moving magnets having small areas of a sized comparable to that of the target surface. When using pulsed powerful discharges this problem is present already at cathodes of small dimensions. If a reciprocating motion of a magnet across a large target surface is used, the peak pulsed discharge power can still have a moderate magnitude but the sputtering target surface can be as large as necessary for practical use.

Magnetrons comprising reciprocally mobile magnets are described in published European patent application 1070767, U.S. Pat. Nos. 5,328,585, 5,873,989, and European published patent application 1120811, the magnetrons having conventional geometric configurations of their magnetic fields.

One specific feature of the magnetic plasma reactor that is described herein includes that as vapor injectors into the reactor reciprocally moving magnets are used providing a high rate of target utilization, see the cited U.S. Pat. Nos. 6,458,252 and 5,306,407 and the cited International patent application WO 01/77405.

Another important feature is that the chemisorption filter is designed to have a getter/sorption surface configuration and an orientation thereof along the magnetic field.

Thus, it is an object of invention to provide CFs that are transparent for metal and gas plasmas and are not transparent for neutral vapor.

It was found that it is possible to obtain such CF properties by applying a magnetic field having a direction parallel to the direction of getter/sorption surfaces. Such a magnetic field is produced by a solenoid assembly located outside the anode tube and coaxial therewith. The length of the solenoid has to be equal to or longer than the anode tube. The getter/sorption surface can be arranged by set of coaxial cylinders placed inside the anode tube having shapes similar to that of the anode tube. The cross-sectional shape of the anode tube is in turn similar to the shape of the magnetron sputtering cathode. It is a circular cylinder shell in the case of a circular magnetron and a rectangular cylinder shell for a rectangular magnetron. Also, the getter/sorption surfaces can be provided by a plurality of parallel plates located inside the anode tube or as two sets of parallel plates placed perpendicularly to each other and placed inside the anode tube. The dimensions and the configuration of the getter/sorption surfaces strongly affect the filter length and the efficiency of the filter.

Thus generally, in a method of magnetically enhanced sputtering and plasma deposition a plasma source unit and a work piece processing unit are used. The plasma source unit has an inner space called the anode space, discharge chamber or space or filter space, and the work piece processing unit has an inner space called the processing chamber. The anode space and the processing chamber are directly coupled to each other to provide a vacuum vessel in which a vacuum, i.e. a relatively very low pressure, is provided and to which sputtering and reactive gases are provided. A work piece to be coated is placed the processing chamber. The anode includes primarily the walls of the anode space. The cathode is a magnetron sputtering cathode that is electrically insulated from the anode and is located at an end of the anode space at which the anode space is not connected to the processing chamber and hence at the end that is remote from the processing chamber. Periodically repeated voltage pulses are applied between the anode and the magnetron sputtering cathode in such a manner that pulsed electric discharges are produced in the anode space, between the magnetron sputtering cathode and the anode, the discharges occurring primarily between the magnetron sputtering cathode and those portions of walls of discharge chamber that are located adjacent to the magnetron sputtering cathode.

To allow coating of relatively large and/or three-dimensional work pieces, a stationary magnetic mirror trap is arranged in the vacuum vessel by suitably placed electromagnetic coils. The trap has an axis that in a preferred case substantially coincides with that of the vacuum vessel.

In the magnetic mirror trap, the magnetic field of the trap can be produced mainly by two electromagnetic coils which are mounted outside the vacuum vessel. A first coil can surround the anode space and a second coil can be mounted at a wall of the processing chamber opposite the end at which the plasma source is connected.

The magnetic mirror trap can be considered as generated mainly by an anode coil and a work piece magnet assembly located at a remote end of the process chamber, behind the position of a work piece, seen from an outlet of the plasma source, the generated magnetic field guiding inside the process chamber charged particles from the plasma outlet and past or beyond the position of the work piece.

Filtering can be used, the filtering performed in the anode space using a chemisorption filter for preventing the reactive gas to reach the region of the anode space adjacent to or at the magnetron sputtering cathode.

In applying the periodically repeated voltage pulses, the electric discharges can simultaneously produce a vapor of a solid material by sputtering material of a target in the magnetron sputtering cathode and a partial ionization of the vapor of a solid material and also of the sputtering and reactive gases to provide plasmas of a solid material and gases. The vapor of the sputtering material is then advantageously deposited onto a chemisorption filter that is located in the anode space and is used as a getter for reactive gas entering the anode space. The plasmas of a solid material and gases are preferably made to flow along magnetic field lines from the anode space into the processing chamber. The ionization rate of the vapor of the sputtering material can be varied, such as by varying the average power of the electric discharges.

The chemisorption filter can comprise layers of a solid material obtained from the vapor of the sputtering material as produced by the discharges and deposited or condensed onto walls of the anode space. The layers then act as a getter for the reactive gas/gases. The areas of the layers located on portions of walls of the anode space located remotely or at distance from the magnetron sputtering cathode are particularly effective and important in the gettering. The layers can in particular layers deposited on surfaces of special filter parts located inside the anode space. These surfaces of the filter parts are then preferably oriented along magnetic surfaces or field lines, in particular along the magnetic surfaces or field lines of the mirror magnetic trap.

Hence, the plasmas of a solid material and of the gases are used for deposition onto one or more work pieces located in the processing chamber and placed inside the mirror magnetic trap.

The electromagnetic coils of the magnetic mirror trap can produce magnetic fields that have substantially identical spatial configurations of the their magnetic force lines and/or substantially identical spatial distributions of their magnetic field strengths.

The magnetron sputtering cathode can include a permanent magnetic system producing a magnetic field having a balanced or an unbalanced configuration. The magnetic field having a balanced or unbalanced configuration can then include magnetic force lines, the main or substantial portion of which are located at a distance equal to or smaller than substantially 1 cm from the surface of the magnetron sputtering cathode and which cross this surface at least twice at the radial distance between the center and the external edge of the surface of the magnetron sputtering cathode.

The direction of the magnetic field of the stationary magnetic mirror trap at an axis is preferably opposite to the direction of a magnetic field produced by a permanent magnetic system included in the magnetron sputtering cathode. The direction of the magnetic field produced by the electromagnetic coils that mainly provide the stationary magnetic mirror trap is at an axis opposite to the direction of a magnetic field produced by a permanent magnetic system included in the magnetron sputtering cathode.

The magnetron sputtering cathode can in a preferred case have a planar circular geometry and include a rotating magnet of dimensions smaller than those of the magnetron sputtering cathode. In another preferred case the magnetron sputtering cathode also has a planar rectangular geometry but includes a circular or rectangular magnet that is arranged to be reciprocally moving in a direction parallel to long sides of the rectangular shape of the magnetron sputtering cathode.

The periodically repeated voltage pulses can be applied so that the parameters of electric discharge pulses arising between anode and cathode in a pulsed voltage include at least one of the following:

a voltage before anode-cathode gap breakdown in the range of 70-7000V, in particular 300-3000 V,

a pulse current shape that is substantially rectangular,

an amplitude of the pulsed current in the range of 100-10000 A, in particular 500-5000 A,

a pulse time in the range of 0.01-1 ms, in particular 0.2-1 ms,

a ratio of pulse length to time between pulses in the range of 0.01-1, in particular 0.1-0.5, and

a pulse repetition frequency in the range of 10-15000 Hz, in particular 100-5000 Hz.

The magnetic mirror trap can be obtained by arranging a single work piece processing unit and two plasma sources located at the same axis and connected to the work piece processing unit, so that the processing chamber and the anode spaces of the two plasma sources together form the vacuum vessel. The magnetic mirror trap can then be made to be positioned symmetrically according a center plane of the vacuum vessel. The magnetron sputtering cathodes of the two plasma sources can then be mounted outside of the mirror portions of the mirror magnetic trap. The two plasma sources can both include chemisorption filters located in their anode spaces.

The magnetron sputtering cathodes of the two plasma sources can both to include rotating or reciprocally moving magnets. The magnets can have motions which are synchronized with each other in such a way that both magnets produce magnetic fields always having a fixed spatial relationship to each other, as seen or taken in directions parallel to a common axis of the two plasma sources. Thus, the magnetic fields can e.g. be always located opposite each other, as seen or taken in directions parallel to a common axis of the two plasma sources. The motions of the moving magnets can be so that both of them produce magnetic fields substantially always located at different portions of the respective magnetron sputtering cathodes, the portions being different as seen in directions parallel to a common axis of the two plasma sources. Also, the motions of the moving magnets can be synchronized with each other in such a way that they always have a fixed spatial relationship to each other, e.g. so that the moving magnets always are located opposite each other, taken in directions parallel to a common axis of the two plasma sources.

The periodically repeated voltage pulses applied to the two plasma sources are then preferably applied so that the starts of the electric discharges produced between the anode and the respective magnetron sputtering cathode coincide in the time, or so that the starts of the electric discharges are delayed by a predetermined time Δt, i.e. so that the discharges in one of the two plasma sources are delayed by the predetermined time Δt compared to the discharges in the other one of the two plasma sources. The delay Δt can be variable in the range of 0.1-1 ms, preferably 0.2-0.5 ms.

The mirror magnetic trap can in also have cusped magnetic field produced by four plasma sources, each plasma source then preferably including a chemisorption filter. The periodically repeated voltage pulses in the four plasma sources can be produced to make the starts of the electric discharges between the anode and the respective magnetron sputtering cathode of each of the four plasma sources coincide in time. Alternatively, the periodically repeated voltage pulses in the four plasma sources can be produced to make the discharges between the anode and the magnetron sputtering cathodes of two opposite ones of the four plasma sources coincide in time. Then, the periodically repeated voltage pulses can be produced to make the discharges between the anode and the respective magnetron sputtering cathodes of one pair of plasma sources located opposite each other to be shifted or delayed in time by a predetermined time period Δt in relation to the discharges between the anode and magnetron sputtering cathodes of the other pair of plasma sources located opposite each other. In still another alternative, the periodically repeated voltage pulses in the four plasma sources can be produced to make the discharges between the anode and magnetron sputtering cathode of the four plasma sources occurring sequentially after each other in a clockwise or anticlockwise direction, the start of a discharges in one of the four plasma sources being delayed by a predetermined time Δt in relation to the start of a discharges in a directly previous one of the four plasma sources.

A device or installation for reactive magnetron sputtering thus comprises a plasma source for generating a plasma and having a plasma outlet and a process chamber connected to the plasma source at the plasma outlet for receiving plasma, the process chamber arranged to contain a work piece to be coated with material. The plasma source in turn preferably includes a pulsed power supply for applying voltage pulses between an anode and a cathode to make discharges between the anode and cathode producing electrons. The cathode includes in the conventional way a metal target from which metal material is to be sputtered and a cathode magnet assembly for providing a magnetron magnetic field having a magnetron configuration at a surface of the target for trapping electrons in the magnetron magnetic field. A discharge chamber magnet assembly, also simply called anode space coil or anode coil, is provided for generating a discharge chamber magnetic field guiding charged particles away from the cathode to produce a plasma flow to the plasma outlet.

The discharge chamber and/or work piece magnet assemblies are then connected to generate constant discharge chamber and work piece magnetic fields respectively, these fields together forming the magnetic mirror trap.

Inlets for a sputtering gas and a reactive or processing gas to be ionized and an outlet connected to a vacuum pump are provided and in particular can both the inlet for the sputtering gas and the inlet for the reactive or processing gas be connected to the process chamber.

The sidewalls of the discharge chamber and the walls of the process chamber are preferably electrically connected to each other. The anode can be connected to a ground potential.

Sorption filter plates can located in the discharge chamber and can then be electrically connected to the anode.

The work piece magnet assembly can in an alternative be part of another plasma source similar to the first one, connected by its plasma outlet to the process chamber at said remote end.

The discharge chamber magnetic field inside the discharge chamber is preferably, at least in a region at the plasma outlet, substantially parallel to an axis of the magnetron sputtering cathode and/or of the target and/or the plasma source.

As mentioned above, the magnetron magnet assembly can include at least one moving magnet and this magnet can be constantly moving with a reciprocating motion with a speed in the range of 0.001-10 m/s. It can also be moving with a rotating motion around an axis of the magnetron sputtering cathode with a revolution frequency in the range of 1-100 Hz.

A work piece holder for the work piece can be provided in the process chamber and be arranged to move the work piece in the process chamber, e.g. in a reciprocating motion.

The filter plates that can be arranged in the anode space/discharge chamber can be placed between the cathode and the plasma outlet and have, as indicated above, getter/sorption surfaces for gettering/adsorbing reactive gas ions flowing towards the cathode and neutral particles sputtered from the cathode. The getter/sorption surfaces are preferably substantially parallel to magnetic field lines and can be electrically connected to the anode. They can have cylindrical shapes and be located in such a way that axes of the cylinder shapes coincide with an axis of the anode and the cylinder shapes are similar to the shape of the cathode. Alternatively, the sorption filter plates can include two sets of flat sorption filter plates crossing each other. The sorption filter plates can have distances between them or interspaces in the range of 1-10 cm and heights in the range of 1-30 cm. Furthermore, the sorption filter plates can be located so that the distance between the cathode and the edge of the filter plates located closest to the cathode is in the range of 0.3-3 d or 0.3-3 h where d is the diameter of a circular cathode and h is the width of a linear cathode.

In the case where a second plasma source identical to a first one is connected to the process chamber, it can have an axis coinciding with the axis of the first plasma source. A third plasma source identical to the first one can also be connected to the process chamber and can then have an axis perpendicular to the axis of the first plasma source. In the case where at least two more plasma sources identical to the first one is connected to the process chamber, they can all have axes located in a single plane in which the axis of the first plasma source is also located.

### BRIEF DESCRIPTION OF THE DRAWINGS

The invention will now be described by way of a non-limiting embodiment with reference to the accompanying drawings, in which:

FIG. 1a is a schematic of a magnetic plasma reactor including one chemisorption filter and one magnetron sputtering cathode,

FIG. 1b is a schematic of a magnetic plasma reactor including two chemisorption filters and two magnetron sputtering cathodes,

FIG. 1c is a schematic of a magnetic plasma reactor including four chemisorption filters and four magnetron sputtering cathodes,

FIG. 2a is a diagram of the energetic efficiency of sputtering and vapor ionization as a function of the discharge driving current,

FIG. 2b is a diagram of E×B discharge parameters for stable operation, efficient sputter deposition, and effective vapor and gas ionization as a function of the cathode surface current density,

FIG. 2c is a diagram similar to FIG. 2a of energetic efficiency of deposition and of vapor ionization as functions of the magnetron discharge driving current in pulsed magnetron sputtering using a magnetic solid-gas plasma reactor for oxide deposition,

FIG. 3a is a schematic of a magnetron sputtering cathode having a balanced magnetic field,

FIG. 3b is a schematic of the magnetron sputtering cathode of FIG. 3a also showing an arrangement of permanent magnets of alternating polarities for producing the balanced magnetic field,

FIGS. 3c, 3d are similar to FIGS. 3a and 3b respectively for an unbalanced magnetic field,

FIG. 4a is a schematic of a magnetron sputtering cathode having magnetic force lines which near the cathode surface cross the cathode surface more than twice, obtained by a permanent magnetic system having magnets of the same polarity,

FIG. 4b is a schematic of the magnetron sputtering cathode of FIG. 4a also showing an arrangement of permanent magnets of similar polarities for producing the magnetic field,

FIGS. 5a, 5b, 5c are schematics of magnetrons having a reciprocating motion of the permanent magnet system,

FIG. 5d is a diagram illustrating the result of experimental measurements of time dependent solid plasma dynamics at the surface of an opposite cathode,

FIGS. 6a, 6b are schematics of a chemisorption filter,

FIG. 6c is a diagram of the sputtering and reactive gases pressure distribution when moving from a cathode through a filter,

FIG. 7 is a diagram illustrating results of experimental measurements of the radial distribution uniformity of deposited and etched layers,

FIGS. 8a and 8b are schematics of a “cylindrical”, pulsed sputtering deposition apparatus based of the chemisorption phenomenon,

FIG. 9 is a diagram of the energy distribution of Cu ions after passing the neutral vapor separator, and

FIG. 10 is a schematic of a planar concept sputtering deposition machine.

### DETAILED DESCRIPTION

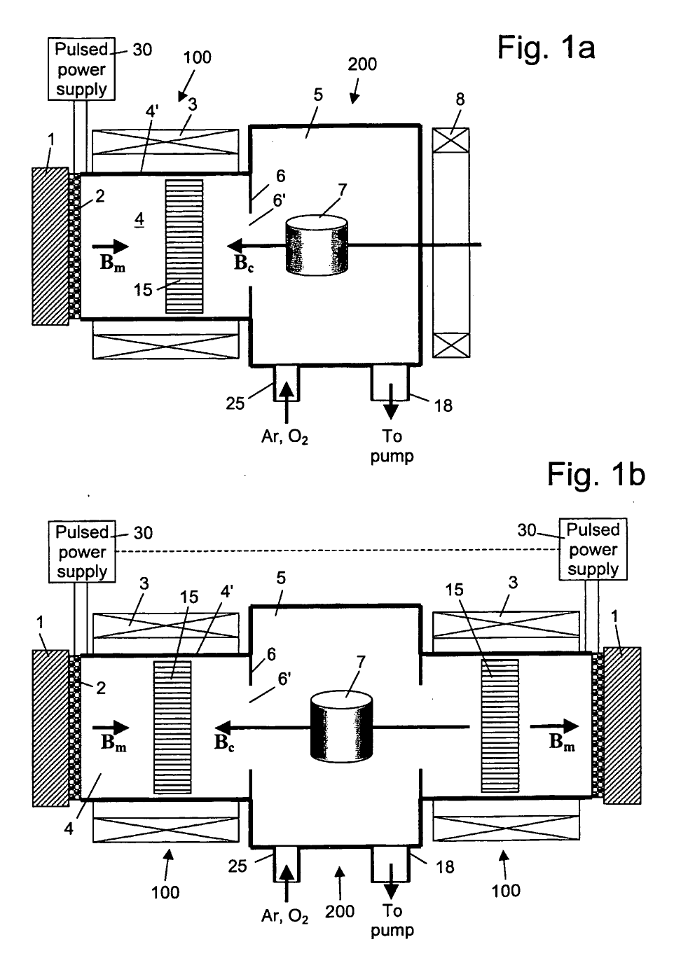

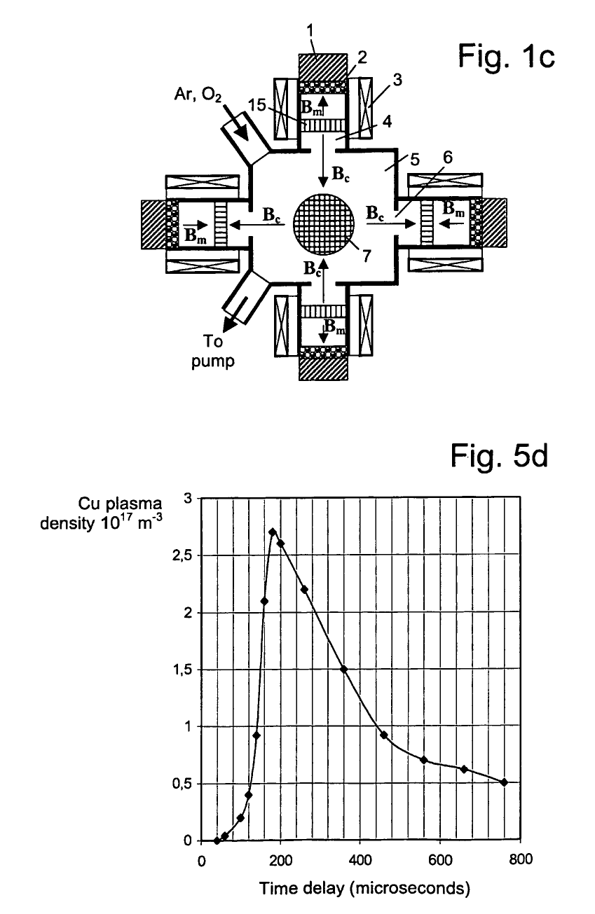

FIG. 1a is a schematic picture of an exemplary magnetic solid-gas plasma reactor, basically built in a way similar to that described in the cited International patent application WO 01/98553 which is incorporated herein by reference, the reactor constituting a device for reactive magnetron sputtering. The plasma reactor includes plasma source unit 100, also called only plasma source, and a work piece processing unit 200. The reactor includes a chemisorption filter CF and is intended for primarily depositing thin films of metal oxide. The reactor has in the unit 100 a magnetron sputtering cathode including a magnet 1 and a cathode or target 2, the free cathode surface forming an end wall of a first vacuum vessel or anode space 4. The reactor has an axis being a geometric axis or a symmetry axis that is perpendicular to said cathode surface and also is the cylinder axis of the anode space. The anode space 4 has cylinder walls 4′ forming the anode of discharge and is surrounded, at its cylinder walls by an anode solenoid 3 used for guiding charged particles and thereby providing a filtering effect. At the end of the anode space opposite the cathode 1 a diaphragm 6, also called partition wall, is located having a central hole 6′ smaller than the cross-sectional area of the anode space 4. The central hole opens into a second vacuum vessel 5, called the processing chamber, in which the work piece 7 is placed, the processing chamber also having a cross-sectional area larger than that of the hole 6′. A second solenoid 8, called a processing chamber solenoid, is placed at the end wall of the processing chamber 5 opposite the central diaphragm hole 6′. The electromagnetic coils 3 and 8 are both placed outside the processing chamber 5 and have axes coinciding with the axis of the reactor. The two coils together create a magnetic field that extends inside the processing chamber 5 and also in other parts of the reactor such as in the first vacuum vessel 4 including the chemisorption filter part. A magnetron magnetic field is provided by the magnetron sputtering cathode 1, 2. The magnetron sputtering cathode acts as a injector of a vapor of solid material into the inner spaces 4, 5 of the magnetic plasma reactor. The chemisorption filter is provided by surfaces of the vacuum vessel or anode space 4 that if required can enclose plates 15 having additional sorption surfaces and also by the inner surface of the diaphragm 6. The magnetic field inside the filter part is created mainly by the electromagnet 3 surrounding the anode vessel. The inner surfaces of the anode walls 4′ of the vacuum vessel 4 are also sorption surfaces. Generally, the chemisorption surfaces can comprise only the inner surfaces of the anode vessel 4, or these surfaces combined with the inner surface of the limiting diaphragm 6, or the inner surfaces of the anode vessel and of the diaphragm together with the surfaces of the filter plates 15.

The anode of the magnetron sputtering discharges includes the two vacuum vessels 4 and 5, the diaphragm 6 and the filter plates 15. The anode is grounded. In other words, the cathode of the discharges is constituted of the magnetron sputtering cathode 2, 1 and the anode of the discharges is constituted of the rest of the electrically conductive parts of the reactor. Because of deposition of dielectric oxides onto the inner walls of the reactor, the effective anode is probably that part of the cylinder walls 4′ that are located near the cathode 2. There, oxidation will be minimal and the deposition rate of conductive aluminum will be highest. Therefore this part of the reactor device will always be electrically conductive. Such a design of a magnetic reactor has been tested and it was found that electrical insulators between the walls 4′, the walls of the process chamber 5, the diaphragm 6 and the plates 15 are not required. This design permits simple water cooling of all anode parts and in particular the filter parts 6 and 15.

The work piece can be biased in some suitable way to e.g. follow the potential of the anode or cathode. The biasing procedure can preferably be as is in detail described in the International patent application PCT/SE2004/001129, having the title “Work piece processing by pulsed electric discharges in solid-gas plasmas”, inventor Vladimir Kouznetsov.

The sputtering gas such as argon and the reactive gas, e.g. oxygen or nitrogen, is supplied into the plasma reactor through an inlet opening 25 into the processing chamber 5. The low pressure in the vacuum vessels 4, 5 is obtained by pumping away gases in the vessels through a pump opening 18 made in a wall of the process chamber 5. The interior of the reactor is initially pumped down up to pressure range of 10⁻³-10⁻⁹ Torr. The range of the operating partial pressure of Ar is 1-10⁻⁹ Torr. The range of the operating partial pressure of O₂ is 1-10⁻⁵ Torr. The sputtering gas, such as a noble gas, e.g. Ar, and the reactive gas such as oxygen can also be injected at different points of the reactor. Generally, the injecting point for the sputtering gas can be located anywhere in the reactor. The reactive gas such as oxygen has to be injected outside the filtering unit, i.e. in the processing chamber 5.

The electromagnetic coil 8 at the far end of the processing chamber 5 is used for extending the magnetic field created by the anode or filter coil 3 into the processing chamber 5, the anode or filter coil located preferably in the filter part of the reactor. Thus, the work piece 7 is located between the anode coil 3 and the processing chamber coil 8. The two coils 3 and 8 provide a coupled magnetic field, meaning that the currents in both coils have the same direction, producing magnetic fields having the same direction at the symmetry axis of the reactor, and that the magnetic flux from the filter coil 3 passes inside the processing chamber coil 8. The two coils can different diameters or have the same inner diameter as illustrated in the figure. The magnetic field Bc generated by the two coils at the axis of the coils and at the axis of the reactor is both for circular and rectangular geometry of the magnetic plasma reactor directed in a direction opposite to the direction of the magnetic field Bₘ generated by the permanent magnetic system 1 for the magnetron located above or behind the sputtering surface of the cathode 2. As follows from the symmetry, the axis of the coil system 3, 8 coincides with that of the magnetron sputtering cathode 1, 2.

The solid and gas plasmas are located between the magnetron sputtering cathode 1, 2 and the opposite side of processing chamber 5. Therefore the work piece 7 is immersed in solid and gas plasmas. The electromagnetic coils 3 and 8 are configured to provide a magnetic trap of mirror kind, see e.g. the textbooks C. L. Longmire, “Elementary Plasma Physics”, Interscience Publishers, 1963, and F. F. Chen, “Introduction to Plasma Physics”, Plenum Press, 1974. The magnetic mirror fields that are located inside the anode coil 3 and near the wall of the process vessel 5 that is opposite to the filter coil 3 and perpendicular to the axis of the two coils 3 and 8 produce the magnetic trap. According to theory and experiment, see the books cited above, the plasma in this kind of magnetic trap is located between the magnetic mirrors. Thus it can be said that the magnetic field of the two coils 3 and 8 confine the plasmas of sputtering and reactive gases and solids inside the processing chamber 5.

The ionization of neutral gases and vapor of solids that is injected into the magnetic trap by the magnetron sputtering cathode is preferably produced by pulsed E×B discharge using a method similar to that described in the cited U.S. Pat. No. 6,296,742. Thus, pulsed discharges are used both for the production of the solids vapor and the ionization thereof as well as for ionization of sputtered and reactive gases. It was found that suitable parameters of the pulsed discharges are as follows:

voltage before anode-cathode gap breakdown in the range of 70-7000V, in particular 300-3000 V

pulse current shape substantially rectangular,

amplitude of the pulsed current in the range of 100-10000 A, preferably in the range of 500-5000 A,

pulse time in the range of 0.01-1 ms, preferably in the range of 0.2-1 ms,

ratio of pulse length to time between pulses in the range of 0.01-1, preferably in the range of 0.1-0.5, and

pulse repetition frequency in the range of 10-15000 Hz, preferably in the range of 100-5000 Hz.

Actually, vapor and gas are ionized in the portion of the device located between the sputtering surface of the cathode 2 and the diaphragm 6 or between sputtering surface of the cathode 2 and the gettering surfaces of the plates 15.

After ionization of solids vapor, the solids plasma is floating along magnetic force lines from the region of the cathode to the central part of magnetic trap because of diamagnetism of plasma, see the textbook by C. L. Longmire cited above. As can be observed, the gas and solid plasmas occupied a much larger volume than the plasma described in the cited International patent application WO 01/98553. The difference between the method as described herein and that disclosed in said International patent application can be demonstrated by switching off the current in the processing chamber coil 8. In that case the magnetic field in the processing chamber 5 is created only by the filter coil 3. The magnetic force lines of this coil mainly cross the nearest parts of the walls of the processing vessel 5, at places where the walls of the anode vessel 4 are connected to the processing vessel, within a distance from the axis of the reactor equal to about the radius of the anode coil 3. Therefore the plasma is not confined but floating to the wall of processing vessel 5. Such a device without an activated reactor chamber coil 8 is thus used as a one-way flight device and therefore only two-dimensional work pieces can be deposited. Such work pieces must be placed as near as possible to the outlet of the anode vessel 4 and they will be deposited only from one side. In the magnetic configuration obtained when the two coils 3 and 8 are simultaneously activated, plasmas are confined almost in all of the volume of the second vacuum vessel 5, i.e. the processing chamber. Therefore, material can also be deposited on three-dimensional work pieces.

FIG. 1b is a schematic of a magnetic plasma reactor including two coaxial identical chemisorption filters 4′, 6, 15 and two coaxial identical magnetron sputtering cathodes 2, 1 that act as solid vapor injectors into the common, central processing chamber 5 located therebetween. The reactor of FIG. 1b can be obtained from that of FIG. 1a by removing the processing chamber coil 8 and mirroring the reactor in a plane through the processing chamber and perpendicular to the axis of the reactor, and adjusting the magnetic fields created by the coils and magnet systems of the magnetron sputtering cathodes as will be described. The electromagnetic coils 3 of the anodes for guiding charged particles along the filters provide coupled magnetic fields. The magnetic fluxes generated by the filter coils 3 are equal to each other. The direction of the magnetic field Bc produced by the two identical electromagnetic coils is at the symmetry axis of the reactor opposite to the direction of the magnetron magnetic field Bₘ, produced by the magnets of the two magnetron sputtering cathodes, the magnetron magnetic fields of the two magnetron sputtering cathodes having the same direction.

In this configuration the two anode coils 3 produce a magnetic trap. The main difference of this configuration compared to that illustrated in FIG. 1a is that there are two metal vapor injectors for injecting into the magnetic trap, the vapor ionization produced by pulsed E×B discharges as above. Actually, vapor and gas are ionized in portions of the inner space of the reactor between the sputtering surfaces of the cathodes 2 and the respective inner surfaces of the diaphragms 6 or between the sputtering surfaces of the cathodes 2 and the respective gettering surfaces of the plates 15.

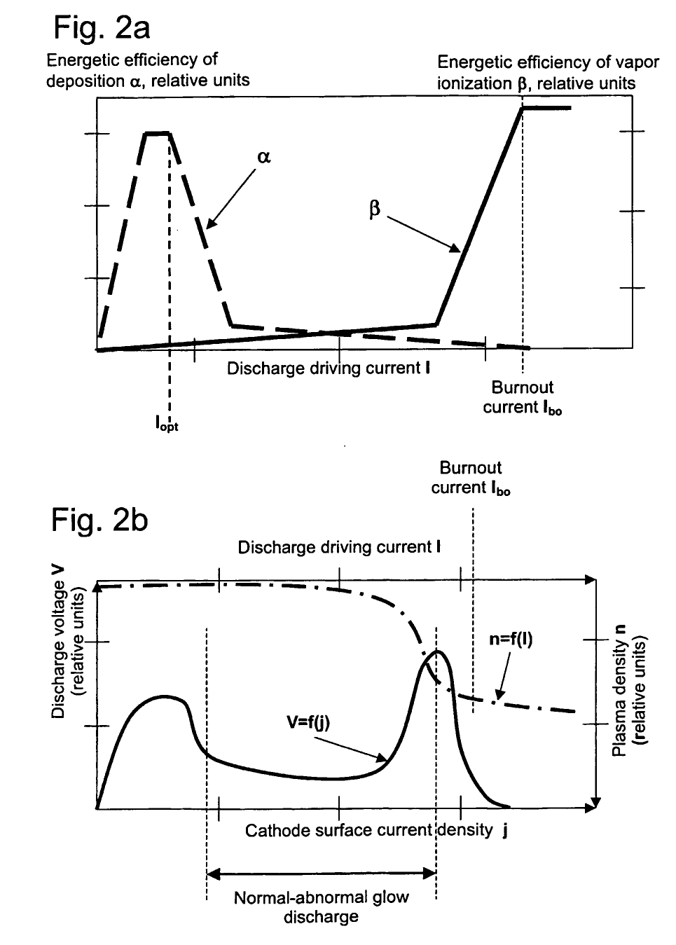

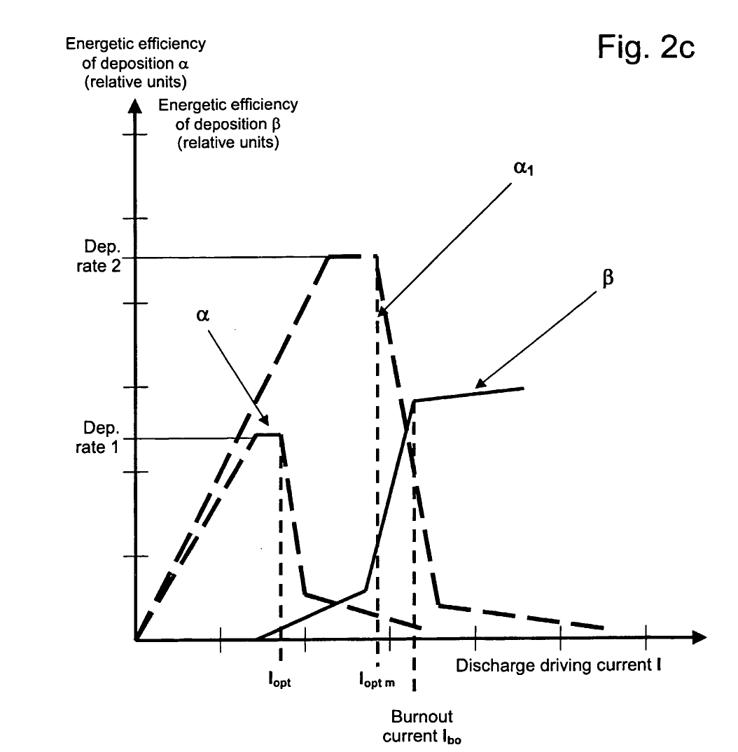

The two metal vapor injectors or plasma sources of FIG. 2 can also have their axes forming an angle with other, e.g. an angle of 15-45°.

FIG. 1c is a schematic of a magnetic plasma reactor including four identical chemisorption filters and four identical magnetron cathodes injecting solid vapor into the common processing chamber 5 located therebetween, centrally in the reactor. The reactor of FIG. 1c can be obtained from that of FIG. 1a by removing the processing chamber coil 8 and rotating the reactor around a center axis of the processing chamber that is perpendicular to the axis of the simple reactor, the rotation then being in a plane through said axis, the rotation being made by 90°, 180° and 270°. The coils 3 of the fours filters produce coupled magnetic fields. The magnetic fluxes generated by the coils are equal to each other. The direction of the magnetic field produced by one opposite pair of filter coils 3 is perpendicular to the direction of the magnetic field of the other pair. The directions of the magnetic fields Bc produced by each of the electromagnetic filter coils 3 is at the corresponding axis opposite to the direction of the magnetron magnetic field Bₘ at the surface of the corresponding magnetron sputtering cathode.

In this case, four magnetic mirrors produced by the four anode coils 3 produce a cusped field or cusped magnetic trap, see S. Glasstone and R. H. Lovberg, “Controlled Thermonuclear Reactions”, D. Van Nostrand Company, Inc. Princeton, N.J., 1960. The advantage of this structure is a larger capacity of the plasma reactor of this type compared to the reactors illustrated in FIGS. 1a and 1b. The principles of solids vapor and plasma production as well as gas plasma production and confinement of all plasmas are the same as for the reactors illustrated in FIGS. 1a and 1b.

The configuration of the magnetron magnetic field is the deciding factor affecting the efficiency of vapor production in the anode vessel 4 in which ionization of the vapor takes place. It was found that conventional balanced and unbalanced magnetrons, see B. Window and N. Savvides, “Charged particles fluxes from planar magnetron sputtering sources”, J. Vac. Sci. Technol., Vol. A 4 (2), March/April 1986, pp. 196-202, have an optimal integral discharge current Iₒₚₜ corresponding to maximum energetic efficiency of vapor production, see the diagram of FIG. 2a, line α. This current is much smaller than the burn out current I_{bo} required for high energetic efficiency of vapor ionization, see the same diagram, line β.

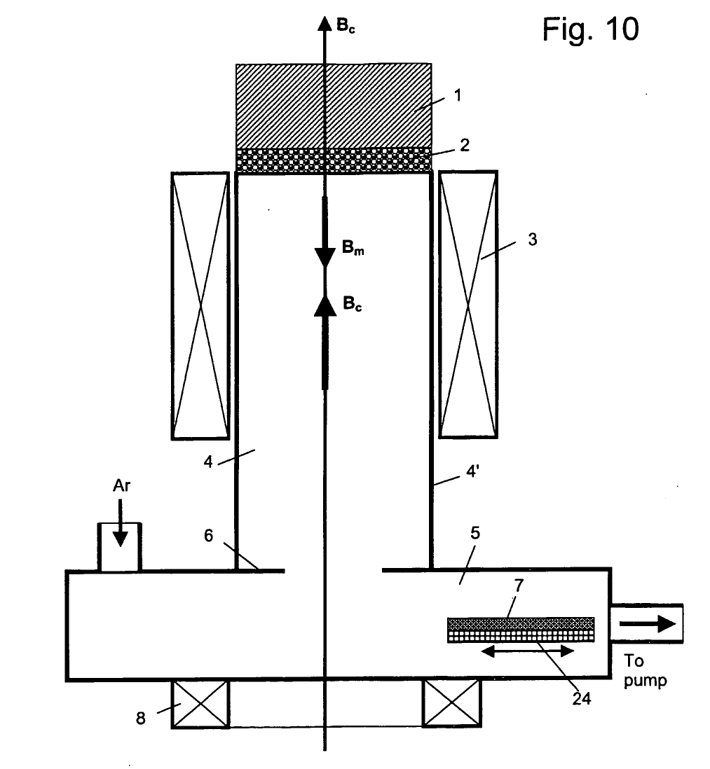

It was found that corresponding to the maximum energetic efficiency the cathode surface current density belongs to the region of normal and abnormal glow discharge, see the diagram of FIG. 2b, line V=f(j). For definitions of different types of discharges reference can be made to J. R. Roth, “Industrial Plasma Engineering”, Vol. 1: Principles, page 353, Fig 10.1. Bristol and Philadelphia: Institute of Physics Publishing, 1995.

On the other side, for conventional magnetrons the current density at the cathode surface corresponding to I_{bo}, the current required for high efficiency of ionization, belongs to the region of arc discharge. As disclosed in the cited U.S. Pat. No. 6,296,742, the entire teachings of which are incorporated herein by reference, for a short time the magnetron kind discharge can possibly also occur in the region of currents corresponding to an arc discharge but as it was found that this regime is very unstable, and the magnetron discharge is quite often transformed into an arc discharge. This drawback is much reduced in the method using double pulses described in the published International patent application WO 02/103078, the entire teachings of which are included herein by reference, but still the probability of arc formation is much higher than for conventional magnetrons operating in the DC regime. Therefore, because of a low efficiency of vapor production and a high probability of arc formation, conventional magnetrons are not very suitable for pulsed magnetron sputtering of a low duty cycle and high power sputtering as disclosed in the cited U.S. Pat. No. 6,296,742 and the cited International patent application WO 02/103078.

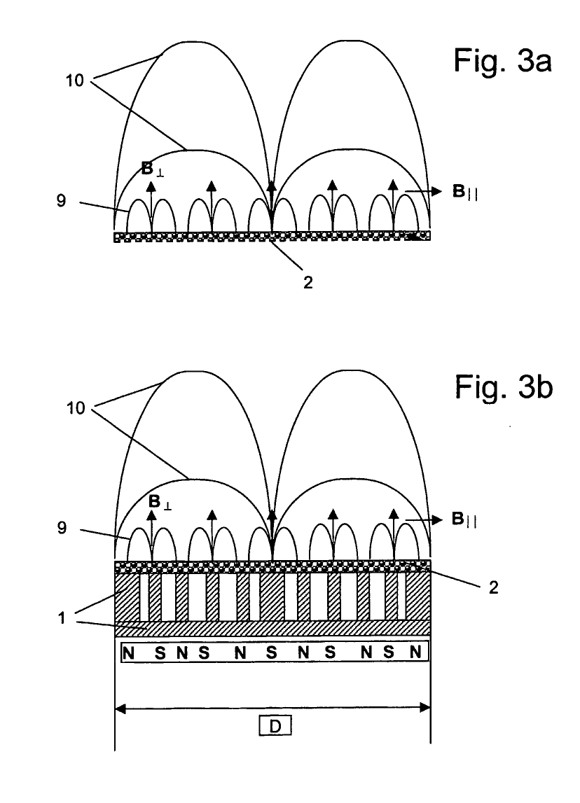

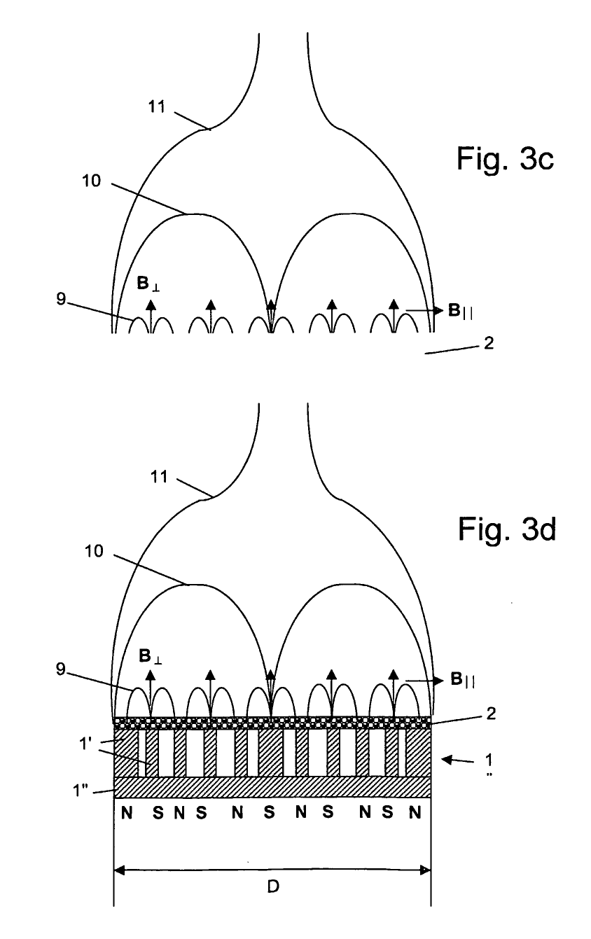

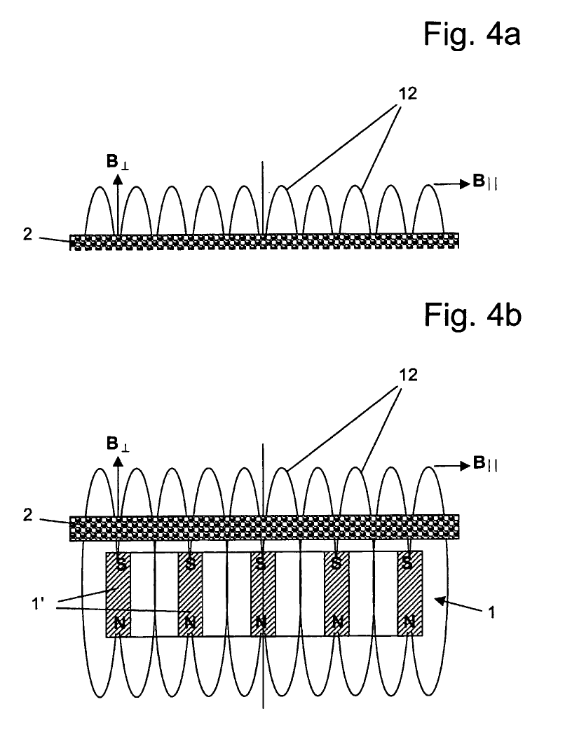

It was found that it is possible to eliminate these two problems by a specific arrangement of the magnetron magnetic field. This specifically arranged magnetic field should result in discharges producing two and more erosion tracks at the magnetron sputtering cathode surface, see the diagram of FIG. 2c and the schematics of FIGS. 3a, 3b and 4. This method can be represented as assembling two and more magnetrons at the same cathode or by other words as a method based on homogeneous distribution of the discharge current across the surface of the magnetron sputtering cathode, see the cited U.S. Pat. Nos. 6,296,742, 5,306,407, 6,458,252, 6,432,285, the cited published International patent applications WO 01/77405, WO 03/041113 and WO 01/77405 and the information presently found at the Internet sites www.gencoa.com and www.angstromsciences.com.

If the discharge current is homogeneously distributed at the surface of the cathode 2, it is possible to achieve a high integral discharge current corresponding to the burn out current I_{bo}, see the diagram of FIG. 2c, line β, by a low current density at the magnetron sputtering cathode corresponding to normal and abnormal glow discharges. It results in a high energetic efficiency of vapor production, see FIG. 2c, I_{opt m}, line α₁, and a low probability of arc discharge.

There is one more positive effect of a homogeneous distribution of discharge current across the cathode surface. It is the high absolute value of the deposition rate, comparable to that of magnetrons having conventional magnetic fields, see FIG. 2c, deposition rates 1 and 2.

Suitable magnetic field configurations are shown in FIGS. 3a, 3c and 4a and permanent magnetic systems suited to produce these configurations are shown in FIGS. 3b, 3d and 4b.

FIG. 3a is a schematic of a balanced magnetron field, see in particular the magnetic force lines 10. The magnetic force lines 9 near the surface of the cathode 2 cross the cathode surface more than twice, in the area between the outer limiting line of cathode sputtering area and the cathode axis.

FIG. 3c is a schematic of an unbalanced magnetron field, see the magnetic force lines 11. As in FIG. 3a, the magnetic force lines 9 near the cathode surface cross the cathode surface more than twice, in the region between outer the limiting line of the cathode sputtering area and the cathode axis.

The magnetic systems 1 shown in FIGS. 3b and 3d, adapted to produce magnetic fields respectively corresponding to those depicted in FIGS. 3a and 3c comprise a sequence of concentric cylindrical, circular or rectangular annular or frame-like magnets 1′ having reverse or alternating polarities. At their sides remote from the cathode 2 the magnetic field can be closed by a disc 1″ of soft magnetic material.

A magnetic arrangement having magnetic force lines near the cathode surface crossing the cathode surface more than twice can also be obtained as seen in FIG. 4a. The magnetic system 1 illustrated in FIG. 4b producing the field depicted in FIG. 4a comprises a sequence of concentric cylindrical, circular or rectangular annular or frame-like magnets 1′ having the same polarity. In this case no closing rear plate 1 is required.

Also other alternative permanent magnet arrangements can be used, some of them possibly being even more efficient.

The possibility of energetically efficiently filling the plasma reactor with solid plasmas open new possibilities for system operation without a sputtering gas and at an extremely low partial pressure of the reactive gases in the region between the chemisorption filter and the sputtering cathode surface. This regime is of high importance for deposition of nonconductive metal oxides, for example γ phase crystalline Al₂O₃ that are used as hard coatings of cutting tools, see the published European patent application 1253215, U.S. Pat. No. 6,451,180 and published U.S. patent application 2003/027,015. In this regime there will be no noticeable dielectric coatings of the discharge electrodes that are the main cause of transformation of magnetron discharges into arc discharges. Additionally, this regime allows obtaining better properties of conductive oxide films, in particular Transparent Conductive Oxides (TCO) such as ZnO, SnO₂ and ITO, see the cited published European patent application 1070767.

In the self sustained magnetron sputtering regime the solid vapor production can be obtained only by the phenomenon of self-sputtering. There are three factors influencing the self-sustained operation. They include self-sputtering yield, solid plasma lifetime in the magnetic reactor and the repetition frequency of discharge pulses.

For obtaining the self-sputtering regime it is necessary to have the magnitude of the self-sputtering yield exceeding one (the unit). The magnitude of the self-sputtering yield depends on the energy of ions bombarding the cathode. Available data show that in order to have a value more than one for all solids, it is necessary to have the energy of bombarding ions in the range of 5-7 keV. It means that for self-sputtering discharges, the discharge driving power supply 30 has to have a terminal voltage of up to 7 kV. Another problem that has to be solved is the decreasing time between pulses or in other words the increasing repetition frequency of discharge pulses. It is so because between plasma generating pulses, the plasma density rapidly decreases because of particle losses from the magnetic reactor and because of the recombination process. If the time between pulses is too long, the initial solid plasma density can be so small at the beginning of the next discharge that the magnetron regime cannot be achieved and only an extremely low current Penning discharge is possible. This type of discharge has no importance for coating work pieces. Therefore, another task for achieving self-sustained vacuum magnetron discharges is increasing the repetition frequency of the plasma generating discharges. This frequency is in high power pulsed magnetron sputtering used for solid vapor ionization limited by the average power flux towards the magnetron sputtering cathode and cannot be higher than 500 Hz and the duty cycle must be smaller than 0.1. The duty cycle is the ratio of the length of the pulses and the length of the repetition time period of the pulses. A frequency of 500 Hz is the upper limit for motionless, geometrically fixed magnets of the kind discussed above.

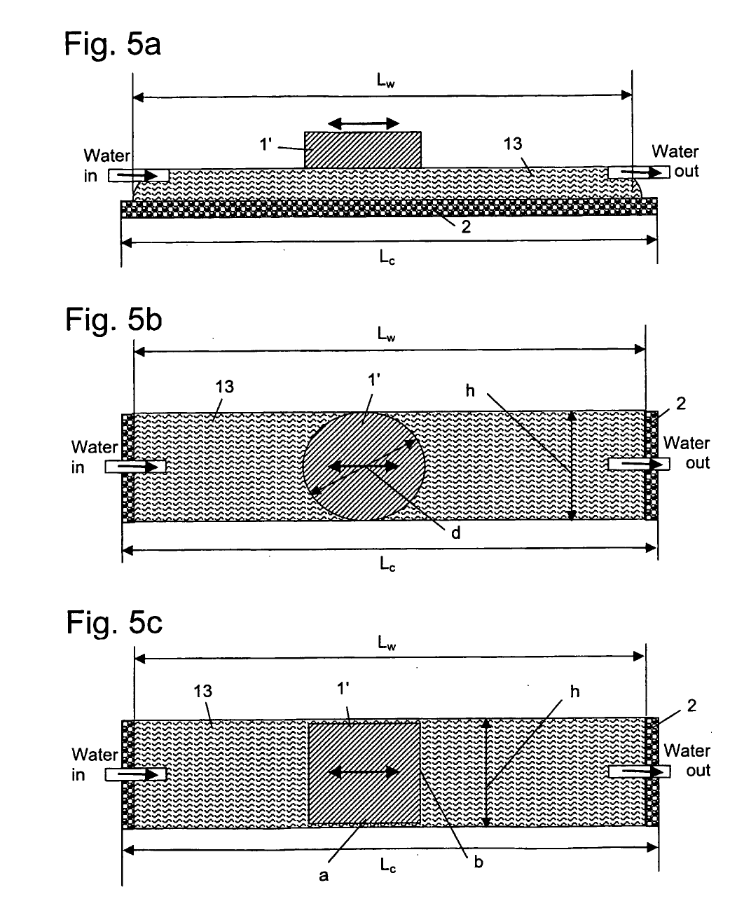

However, for small circular or rectangular magnets having a reciprocating motion along a linear target, see the schematics of FIGS. 5a, 5b and 5c, the pulse repetition frequency can be much higher. It was found that for this restriction of the magnetron, the upper limiting repetition frequency of the discharge pulses is 15 or preferably 5 kHz and the duty cycle can have any value up to one. The limits of these parameters for the magnetron schematically shown in FIGS. 5a, 5b and 5c, operating in the self-sustained regime, are 10-15000 Hz or preferably 100-5000 Hz and 0.01-1.

The same method can be used in systems having small magnets rotating around the axis of a large target as described in the published European patent application 1174902, the published U.S. patent applications 2003/008,9601, 2002/000,8017, 2002/0148,725 and U.S. Pat. No. 6,413,382.

In the linear cathode shown in FIG. 5a, the mobile magnet 1′ is movable along the rear surface of the cathode 2, that has the length L_{c} and is shown to have a water-cooled area 13. The length of the water-cooled area is L_{w}. The length of the reciprocating motion distance, shown by arrows in the figures, of the mobile magnet 1′ is equal to or less than the length L_{w}. The width of the water cooled area is equal to the width h of the sputtering cathode. For a mobile magnet that is circular, see FIG. 5b, the diameter d of the magnet is equal to or less than the width h. For a small mobile magnet 1′ that is rectangular, see FIG. 5c, the width b of the magnet is equal to or somewhat smaller than the cathode width h. The length of the rectangular magnet is in the range of 0.1 L_{w}. It was found that for an efficient distribution of discharge power along the cathode surface, the mobile magnet 1′ has to have a speed of reciprocating motion e.g. in the interval of (1·10⁻³−10) m/s. The mechanism for moving the magnet can be based on hydraulic, pneumatic or electric drivers. The width h of the cathode is typically from 3 cm up to 30 cm. The length L_{c} of the cathode is typically in the range of 10 cm-10 m.

Such a magnetron comprising a mobile magnet that produces a uniform distribution of discharge current over the cathode surface has the following advantages compared to magnetrons having dimensions of their fixed magnet equal to the sputtering cathode surface:

a high rate of target utilization.

a low price of the permanent magnets assembly.

a low pulsed power of the discharge driving power supply.

a low cost of the pulsed discharge driving power supply.

However, it should be observed that a magnetron having dimensions of its motionless magnet equal to those of the sputtering cathode surface can be also used. For magnetrons operating simultaneously typically the pulse repetition frequency is in the range of 10-500 Hz and the duty cycle is smaller than 0.1, simultaneous operation meaning that the starts of the discharges between the anodes and each of cathodes occur simultaneously or are synchronized with each other.

Another way of magnetic plasma reactor operation is based on non-simultaneous operation of magnetrons having fixed, motionless magnets, such operation meaning that the starts of the discharges between the anodes and each of cathodes are not simultaneous but are synchronized with each other. This method is illustrated by the diagram of FIG. 5d in which the time dependence of the plasma density near the opposite magnetron in a reactor having two opposite magnetron sputtering cathodes, see FIG. 1b, is shown. It was found that there is a significant delay of the arriving time of the plasma blob—for definition of the term “plasma blob”, see the cited International patent application PCT/SE2004/001129, to the opposite cathode surface. The time delay depends on the distance between the two cathodes 2. In FIG. 5d the maximum density of a Cu plasma corresponds to a delay of about 200 microseconds and the plasma decay time is about one millisecond. The regime of magnetic metal plasma reactor operation that uses this phenomenon is implemented by a delayed pulsing of the opposite magnetron in the double magnetron configuration of FIG. 1b, or of neighboring magnetrons in the multiple magnetron configuration of FIG. 1c. In the plasma reactor having four magnetrons, one thereof can ignite two neighboring magnetrons that are coupled by joint magnetic force lines if both of them are powered. The magnetic flux of each of the four magnetrons is split into two equal parts. These parts of magnetic flux are coupled with two neighboring magnetrons. After the plasma blob has been created, it follows the magnetic field lines to move in two directions to the two neighboring magnetrons. In other words, the plasma blob is split as well. It means that the plasma blob that is produced by one of the four magnetically coupled magnetrons can produce conductive media near the two neighboring magnetrons. After the plasma has arrived to the region between the cathode 2 and the portion of the anode cylinder 4′ that is located adjacent thereto, the magnetron discharge can start in one of two neighboring magnetron also if only the first one is powered. In this case the other part of plasma blob is not used for ignition and it decays because of losses from the magnetic trap and plasma recombination. The magnetron discharge can also start in the two neighboring magnetrons if both of them are powered. In this case both portions of the split plasma blob are used. This phenomenon significantly simplifies achieving the self-sustained regime of operation and allows it to be maintained for a decreased operating frequency of each magnetron. The self-sustained discharge moving around the axis of the system shown in FIG. 1c is transferred from one magnetron to another. This movement can be in a clockwise or counterclockwise direction. It was found that for a system having four magnetrons the operating frequency in the self-sustained regime is equal to or higher than 100 Hz.

The principle of delayed pulsing of magnetrons located in the same magnetic plasma reactor is of course also applicable to magnetrons having mobile magnets, both rotating and reciprocally mobile magnets. In this case, obtaining the self-sustained regime is much more simplified due to the possibility to run the plasma driving discharge at an elevated frequency that can be up to 15000 Hz but in most cases only up to 5000 Hz.

The operation of small mobile magnetrons at elevated frequencies is possible because small magnets create a magnetron magnetic field located substantially only in a small region at the cathode where the discharge current and power are concentrated. Due to the motion of the magnet, from pulse to pulse the heated area of the cathode is different and in average the discharge power is distributed over a much larger cathode area compared to that of magnetrons having a motionless magnet. The main factor limiting the average discharge power is overheating the cathode. For mobile magnets, since a larger cathode area is heated in average, the average discharge power can be larger. It results that an elevated pulse frequency can be used since the peak pulse power is limited by the phenomenon of transformation of the magnetron discharges into arc discharges and does not depend on magnet-motion.

A specific condition for magnetron discharge pulsing using mobile magnets is that the pulse frequency should not be a multiple of the frequency of magnet revolution around the target axis for rotating magnets or the frequency of magnet oscillation for reciprocally mobile magnets. This conditions results from the fact that if the pulse frequencies would be a multiple of the motion frequency, the pulsed discharges will always occur at the same cathode area and then only part of cathode surface will be heated.

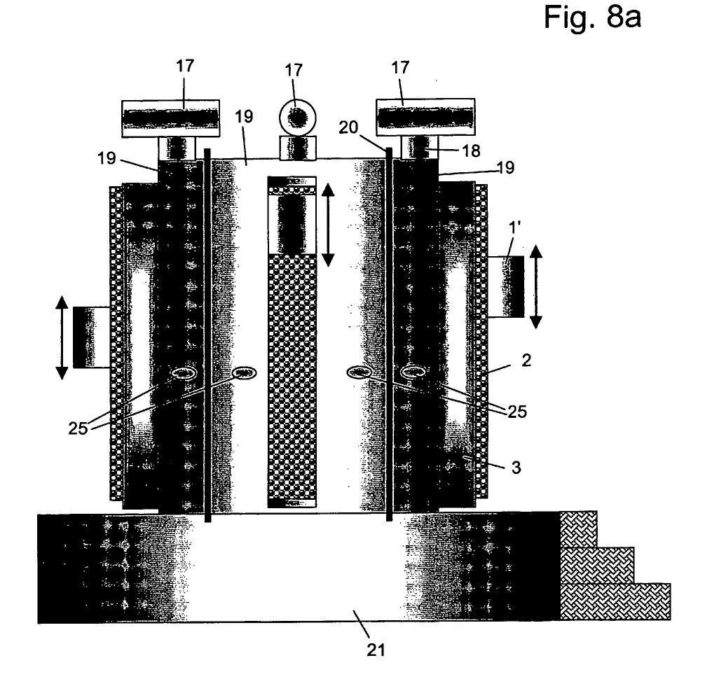

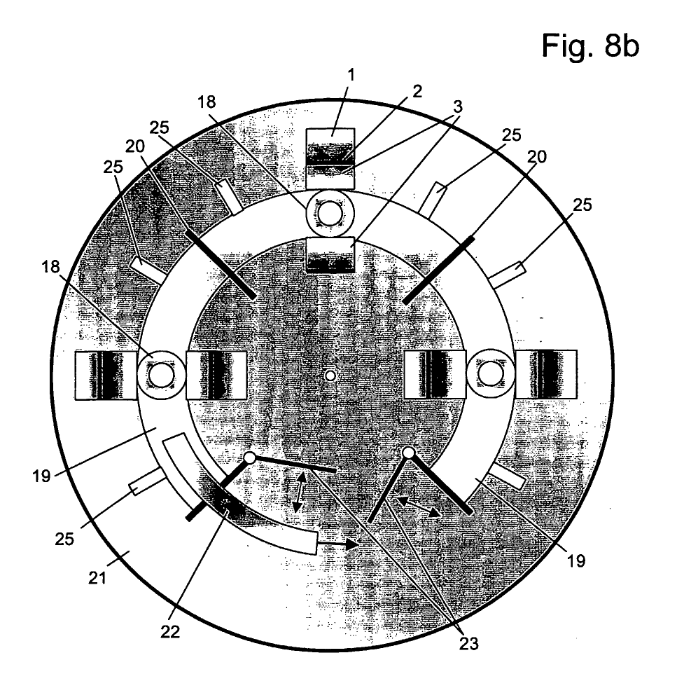

Another specific condition for pulsed discharges in a system using small mobile magnets moving at cathodes having a large area and coupled together by the magnetic field, see FIGS. 1b, 1c and FIG. 8a, 8c, is that the motion of the magnets can be correlated in space, this meaning that the axes of the magnets coincide in space during the motion of the magnets or do not coincide but have the same relative position in space or they can move independently of each other. For a system having more then two cathodes it means that the axes of mobile magnets are placed in the same plane crossing the system axis or not. The difference between systems including magnets moving with coinciding and not coinciding axes can be demonstrated by for example two cathodes facing each other, see FIGS. 1b and 8a, 8b, coupled by the same magnetic flux. If the magnets have coinciding axes and the plasma creating electric discharges is synchronized in time, the two plasma injectors fill the same portion of magnetic flux in the same time. Then the plasma density in this part of magnetic flux is twice that obtained when using random, not synchronized pulses and not coinciding magnet axes. It is so because the movement of charged plasma particles across magnetic field is possible by diffusion and therefore is strongly reduced but the movement along the magnetic force lines is free. For practical use all possible regimes of sputter deposition system operation having mobile magnets and operating in pulsed regime are important.

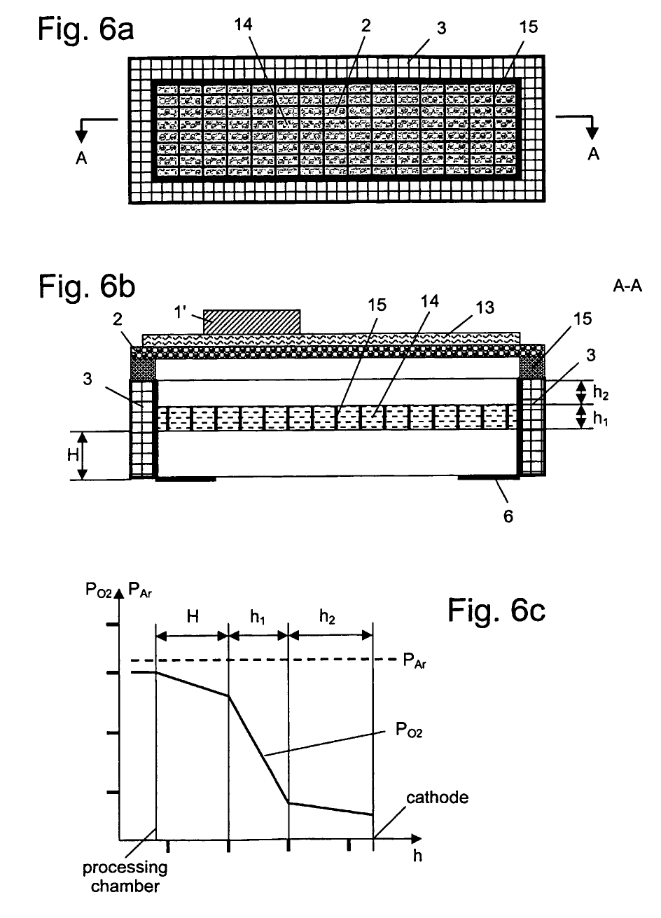

The magnetron sputtering cathode has a double use in a magnetic solid plasma reactor. First it is the cathode of the E×B discharges and second it works as the source of the solid vapor. In the case of operation in an oxygen atmosphere, the electrodes of discharge such as the cathode and the anode have to be protected from oxidation. It is so due to formation of dielectric ceramic layers on these electrodes. Dielectric layers are the main cause of arcing, resulting in formation of droplets and thereby decreasing the quality of deposited films. Furthermore, transformation of the magnetron discharge into an arc discharge can cause damage to the discharge driving power supply. The method of solid plasma production using high power pulsed discharges between the anode and the magnetron sputtering cathode employs a very low frequency, typically a few hundreds of Hz, and therefore the approach based on capacitances to avoid arcing is not useful here. One method that can efficiently solve the arcing problem in the method described in the cited U.S. Pat. No. 6,296,742 is based on pumping oxygen out of the region of the electrodes by a specially designed pump based on the chemisorption phenomenon. The pump that in fact is a chemisorption filter is schematically shown in the schematics of FIGS. 6a and 6b, se also the diagram of FIG. 6c. The sputtering cathode 2 is separated from the anode/chemisorption filter by electric insulators 16. The chemisorption filter can be arranged to include the inner surface of the vacuum vessel 4, i.e. the anode, or this surface and that part of the surface of the diaphragm 6 that faces the magnetron cathode. The filter can be provided to include these surfaces and additionally the surfaces of plates 14, 15 acting as additional getter surfaces, these surfaces and the plates interposed between the cathode 2 and processing chamber 5.

The additional getter/sorption surfaces can be arranged as the surfaces of a plurality of coaxial cylinders, not shown in the figures, located in the anode space 4, having shapes similar to that of the anode walls 4′ and electrically connected to the walls. The cross-sectional shape of the anode tube is in turn similar to the shape of the magnetron sputtering cathode. Thus, it is a circular cylindrical shell in the case of a circular magnetron and a rectangular shell for a rectangular magnetron. The getter/sorption surfaces can also be arranged as the surfaces of a plurality of parallel plates located inside the anode tube or as two sets of parallel plates 14, 15 placed perpendicularly to each other and located inside the anode tube 4. The dimensions and the configuration of the getter/sorption surfaces strongly affect the life-time and efficiency of the filter. The gettering surfaces can have any suitable shape, such as rectangular, polygon, an assembly of rhombs and/or trapeziums or be the surfaces of short pieces of small diameter tubes.

It was found that the distance between coaxial cylinders or parallel plates providing the getter surfaces preferably is in the range of 1-10 cm. The height h₁ of the assembly providing the additional getter surfaces, see FIG. 6b, is preferably in the range of 1-30 cm. The additional getter surfaces are advantageously positioned substantially parallel to the magnetic force lines or to the axis of the reactor. The distance h₂ of the upper edge of the additional getter plate assembly from the surface of the cathode 2, see FIG. 6b, is typically 0.3-3 d, see also FIG. 5b, or 0.3-3 h, see also FIG. 5c.

For activation of the filter a vapor of solid material is used. The vapor is deposited on the surfaces of the getter plates. The magnetron then operates in the regime of partly vapor ionization. The ionized portion of the vapor moves along the magnetic force lines out of the filter into the processing chamber 5. The proportion between solid vapor and solid plasma is varied by varying the discharge current or equivalently by varying the average power of the discharges between anode and cathode. The variation of this proportion is required for adjusting the plasma reactor for operating free of arcing.

It must be observed that the filter is at the same time a separator for neutrals. Therefore, in the processing chamber 5, preferably solid plasma is penetrating. It was found that outside the filter in the processing chamber, for the solid plasma the ratio nᵢ/n₀+nᵢ can be up to 0.98, where nᵢ is the ion density and n₀ is the neutral density.

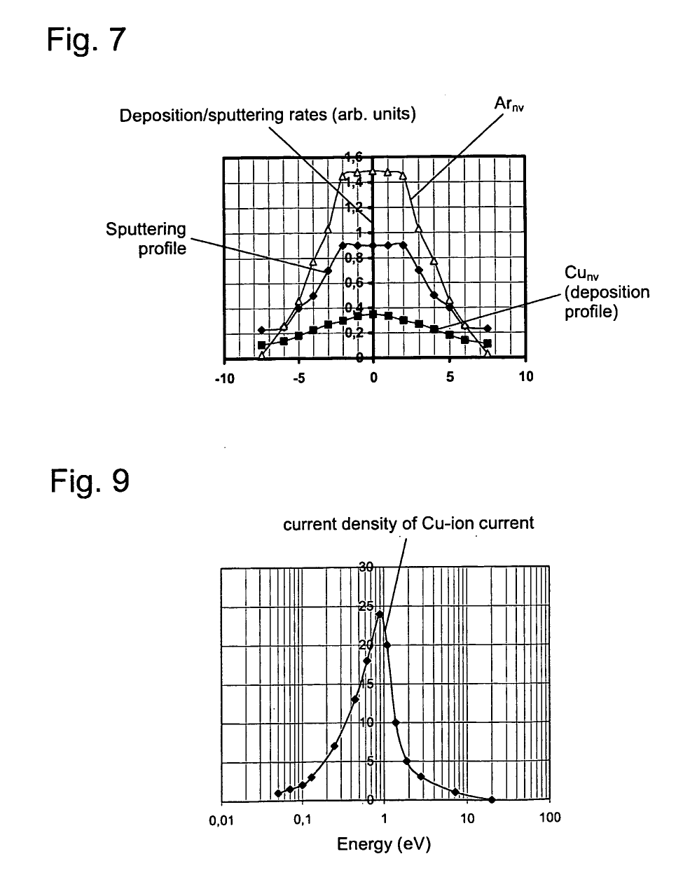

It was found, see the diagram of FIG. 7, that after vapor and gas ionization the magnitude of the product nᵢvᵢ, where vₒ is the ion velocity, both for solid and metal plasmas is very irregular in the radial direction for a circular planar magnetron having a magnetic field according FIGS. 3a and 3b and used as a vapor injector in the magnetic plasma reactor. The same irregularity is typical of a rectangular magnetron in the direction along the dimension h, see FIGS. 5b and 5c. It results in strong irregularities of the thickness of deposited films and as well of the sputtering profile if the work piece and magnets are not moved, i.e. have a fixed position in the operation of the reactor.

The methods and apparatus described above and the characteristic features of plasma and gas dynamics allows different concepts of solid and gas plasmas deposition machines to be designed.

The general principles of machines based on solid and gas plasma production by high power pulsed E×B discharges are the following:

1. The machines based on motionless circular planar magnetrons and motionless work pieces have an area of uniform thickness of deposited and etched layers that has small dimensions and can be used only for processing work pieces of small dimensions.
2. The machines based on clusters of circular magnetrons appear to have little practical value.
3. Most useful for practical work are machines based on linear magnetrons comprising mobile work pieces.
4. Due to technical problems of creating an ultra powerful pulser for large magnetrons, the concept including small reciprocally mobile or rotating magnets is most realistic.
5. Because of low plasma confinement properties of the magnetic plasma reactor shown in FIG. 1c, it is less suitable than the reactors shown in FIGS. 1a and 1b.
6. Because of the limited distance between the coils of the filters, see FIGS. 1a and 1b, a reactor having a planar or cylindrical geometry is preferable.

A planar geometry of the reactor means that planar rectangular magnetrons are mounted externally on two parallel plates that are the opposite walls of the processing chamber 5 and located remotely from each other. These plates can be a disk-shaped or square-shaped. The sidewalls of the reactor are correspondingly circular or rectangular cylinders.

A cylindrical geometry of the reactor means that planar rectangular magnetrons are externally mounted on two concentric circular cylinders, see FIGS. 8a and 8b that have different diameters. In this case the sidewalls of the reactor are flat rings fixed on different sides, i.e. the top and bottom ends of the coaxial cylinders, connecting them to each other. To these rings the vacuum pumps are mounted.

A reactor having a circular cylindrical geometry is shown in FIGS. 8a and 8b. The reactor has been constructed according to a modular concept. Modules 19 are assembled together by mounting flanges 20. The numbers of modules are one or more but their assembling should establish a not closed cylindrical shell configuration. The reactor is placed on a platform 21. Each module 19 is pumped by a horizontal turbo pump 17 through flanges 18. The linear cathodes 2 are attached to chemisorption filters, not seen in these figures, that in turn are attached to the modules 19 at the inner and outer cylindrical walls. In FIG. 8b two reactors modules located according to FIG. 1b and one module according to FIG. 1a are shown, all the modules sharing the same processing chamber 5. The magnetrons have small reciprocally mobile magnets 1 producing a uniform distribution of discharge current over part of the cathode surface. The work piece holder 22 enters the processing chamber through doors 23 that are vacuum-sealed after the work pieces have been loaded. The work pieces have as a minimum a reciprocating motion around the modular circular cylindrical processing chamber axis during processing. For each magnetron, the chemisorption filter and the walls of the processing chambers is the anode of the pulsed E×B discharges that are used for vapor and plasma production. The cathode of the discharges is magnetron sputtering cathode that is electrically insulated from the anode. The chemisorption filter and the walls of the anode and processing chamber are grounded. The work pieces batch is mounted in a frame that is insulated from the anode and cathode. The frame has a reciprocal motion around the vertical axis of the processing chamber. The work piece holders connect mechanically and electrically the work pieces to the frame of the reactor. The frame is disconnected from anode and cathode but can be biased according to the anode or cathode. The biasing can be as suitable but in particular the method disclosed in the International patent application PCT/SE2004/001129 cited above can be used. The work pieces have to have as a minimum a reciprocal motion around the vertical axis of processing chamber together with the frame. Additional work piece motion can be a revolution of the work pieces around an axis of the holders. All kind of motions can be driven by chain transmissions that are connected to electrical motors.

It was found that after passing the chemisorption filter that is at the same time a separator for neutral vapor, the solid ions have a typical energy about 1 eV, see the diagram of FIG. 9, and a ratio v_{i⊥}/vᵢ₌, where v_{i⊥} is the ion velocity perpendicularly to the wafer surface and vᵢ₌ is the ion velocity parallel to the wafer surface, in the range of 0.1-0.05 and for the solid plasma the ratio nᵢ/n₀+nᵢ can be up to 0.98. The deposition rate can be as much as 30-50% of the DC regime by equivalent average discharge power. Thus, this kind of reactor can be used for directional deposition of metal films into high aspect ratio nano-scale vias and trenches for microelectronic application, see the cited published European patent application 1174902, the cited published U.S. patent applications 2003/0089,601, 2002/000,801, 2002/0148,725 and the cited U.S. Pat. No. 6,413,382.

A corresponding simple reactor is shown by the schematic of FIG. 10. This reactor is a magnetic metal plasma reactor alternative to the reactors disclosed in the cited published European patent application 1174902 and the cited published U.S. patent application 2003/0089,601. The drawback of the previously disclosed reactors is that the reactor comprises only one electromagnetic coil or by only one system of permanent magnets located at one side of the substrate to be coated. It results in large radial components of the magnetic field near the surface of the substrate or wafer.

It was found that the plasma, the ions and electrons, move along the magnetic field lines. It results in turn in a large incident angle of ions near the wafer surface. Therefore deposition of metal films into high aspect ratio nano-scale vias and trenches is quite problematic. Another drawback of these previous reactors is so that residual metal vapor remaining after vapor ionization can not be effectively separated.

The reactor of FIG. 10 is similar to that shown in FIG. 1a. The work piece 7 such as a wafer has a reciprocating motion across or perpendicular to the longitudinal direction of the linear magnetron that has a large motionless or small reciprocally mobile magnet, moving in the longitudinal direction of the magnetron, see also FIGS. 5b, 5c. The wafer is mounted on top of a mobile wafer holder 24. Thus, in the latter case, the wafer and the small magnet are reciprocally moving with moving directions perpendicular to each other.

Another version of this reactor is that the linear magnetron 1 including the small reciprocally moving permanent magnet is replaced with a magnetron obtained from a planar circular large surface target and a small permanent rotating magnet, not shown. The magnet is rotating around the target axis. This magnetron can be any type of magnetron having a rotating magnet, in particular magnetrons as disclosed in the cited published U.S. patent applications 2003/0089,601 and 2002/0008,017 and the published U.S. patent application 2001/0,052,456. The rotating magnet can be designed as described herein, see FIGS. 3b, 3d and 4b. The revolution frequency of the magnet is about 1-100 Hz. The electric discharge frequency is not divisible by the revolution frequency, i.e. it is not an integer multiple thereof. The method of magnetron and magnetic plasma reactor powering can be any kind of pulsed and RF methods in the frequency range of 10 Hz-33 Mhz, in particular as disclosed in the published U.S. patent application 2002/0,043,336, the cited U.S. Pat. Nos. 6,413,382, 6,296,742, the cited published International patent application WO 02/103078 and according to B. M. DeKoven, “Carbon Thin Films Deposition Using High Power Pulsed Magnetron Sputtering”, Society of Vacuum Coaters, 46^{th} Annual Technical Conference Proceedings, 2003. The wafer can be mounted on an axially symmetric motionless wafer holder positioned in the processing chamber in such a way that the axis of the wafer holder agrees with the axis of the target or the wafer holder can have planetary motion around the system axis.

It has to observed that a depositing machine having reciprocally moving magnets, see FIGS. 3a, 3b and 3c, obviously can be used also for efficient reactive sputtering deposition of two dimensional work pieces having large areas like architectural glass, or solar panels based on ZnO or SnO₂ (TCO) layers.

1. A method of magnetically enhanced sputtering and plasma deposition comprising the steps of:
providing a plasma source unit and a work piece processing unit, the plasma source unit having an inner space, the anode space, and the work piece processing unit having an inner space, the processing chamber, the anode space and the processing chamber being in direct communication with each other to provide a vacuum vessel,
providing a vacuum in the vacuum vessel,
providing sputtering and reactive gases into the vacuum vessel,
providing a work piece in the processing chamber,
providing an anode being walls of the anode space,
providing a magnetron sputtering cathode electrically insulated from the anode, the magnetron sputtering cathode located at an end of the anode space remote from the processing chamber,
applying periodically repeated voltage pulses between the anode and the magnetron sputtering cathode in such a manner that pulsed electric discharges are produced between the magnetron sputtering cathode and the anode, in particular between the magnetron sputtering cathode and portions of walls of discharge chamber located adjacent to the magnetron sputtering cathode, characterized by the additional step of:
providing a stationary magnetic mirror trap in the vacuum vessel, the trap having an axis substantially coinciding with an axis of the vacuum vessel, the magnetic mirror trap inside the process chamber guiding charged particles from the plasma outlet and past or beyond the position of the work piece and therefrom back again.

2. A method according to claim 1, characterized in that in providing the plasma source unit and the work piece processing unit they are separated by a partition wall having a hole.

3. A method according to claim 1, characterized in that a single magnetron sputtering cathode is provided.

4. A method according to claim 1, characterized in that in providing the stationary magnetic mirror trap, the magnetic field of the trap is produced mainly by two electromagnetic coils mounted outside the vacuum vessel, a first one surrounding the anode space and a second one mounted at a wall of the processing chamber opposite the end at which the magnetron sputtering cathode is mounted.

5. A method according to claim 1, characterized by the additional step of filtering, in the anode space, using a chemisorption filter for preventing penetration of the reactive gas into the region of the anode space adjacent to or at the magnetron sputtering cathode.

6. A method according to claim 1, characterized in that in applying the periodically repeated voltage pulses, the electric discharges simultaneously produce a vapor of a solid material by sputtering material of a target included in the magnetron sputtering cathode and a partial ionization of the vapor of a solid material and the sputtering and reactive gases to provide plasmas of a solid material and gases.

7. A method according to claim 6, characterized in that in producing the vapor of a solid material, the vapor is deposited onto a chemisorption filter located in the anode space and used as a getter for reactive gas entering the anode space.

8. A method according to claim 6, characterized in that in producing the plasmas of a solid material and gases, the plasmas are made to flow along magnetic field lines from the anode space into the processing chamber.

9. A method according to claim 1, characterized by the additional step of providing a chemisorption filter, the filter comprising layers of a solid material obtained from a vapor of solid material, produced by the discharges, condensed onto walls of the anode space, the layers acting as a getter for the reactive gas/gases, in particular areas of the layers located on portions of walls of the anode space located remotely or at distance from the magnetron sputtering cathode.

10. A method according to claim 9, characterized in that in providing the chemisorption filter, the chemisorption filter is made to include layers of the solid material obtained from the vapor of solid material, produced by the discharges, condensed onto surfaces of filter parts located inside the anode space.

11. A method according to claim 1, characterized in that in providing the magnetron sputtering cathode, it is made to have a planar circular geometry including a moving magnet having dimensions smaller than those of the magnetron sputtering cathode, the moving magnet rotating or reciprocally moving in a direction parallel to long sides of the magnetron sputtering cathode.

12. A method according to claim 1, characterized in that in providing the magnetic mirror trap, it is provided by arranging one work piece processing unit and two plasma sources located at the same axis, the processing chamber and the anode spaces of the two plasma sources forming the vacuum vessel.

13. A method according to claim 1, characterized in that in providing the mirror magnetic trap, it is provided having a cusped magnetic field produced by four plasma sources, each plasma source including a chemisorption filter.

14. A device for reactive magnetron sputtering comprising:
a plasma source for generating a plasma and having a plasma outlet,
a process chamber connected to the plasma source at the plasma outlet for receiving plasma, the process chamber arranged to contain a work piece to be coated with material,
characterized by a work piece magnet assembly located at a remote end of the process chamber, behind the position of a work piece, seen from the plasma outlet, for generating a magnetic field which acts as a magnetic mirror trap and inside the process chamber guides charged particles from the plasma outlet and past or beyond the position of the work piece and therefrom back again.

15. A device according to claim 14, characterized in that the plasma source includes:
a pulsed power supply for applying voltage pulses between an anode and a cathode to make discharges between the anode and cathode producing electrons,
the cathode comprising a metal target from which metal material is to be sputtered,
a cathode magnet assembly for providing a magnetron magnetic field having a magnetron configuration at a surface of the target for trapping electrons in the magnetron magnetic field,
a discharge chamber containing the target and having sidewalls connected as the anode,
a discharge chamber magnet assembly for generating a discharge chamber magnetic field guiding charged particles away from the cathode to produce a plasma flow to the plasma outlet.

16. A device according to claim 14, characterized by inlets for a sputtering gas and a reactive or processing gas to be ionized and an outlet connected to a vacuum pump.

17. A device according to claim 14, characterized in that the inlets for a sputtering gas and for a reactive or processing gas are connected to the process chamber.

18. A device according to claim 14, characterized by sorption filter plates located in the discharge chamber and electrically connected to the anode.

19. A device according to claim 18, characterized in that the sorption filter plates have cylindrical shapes and are located in such a way that axes of the cylinder shapes coincide with an axis of the anode and the cylinder shapes are similar to the shape of the cathode or the sorption filter plates include two sets of flat sorption filter plates crossing each other.

20. A device according to claim 18, characterized in that the sorption filter plates have surfaces substantially parallel to the magnetic field or to an axis of the device.

21. A device according to claim 14, characterized in that the work piece magnet assembly is part of another plasma source similar to the first one, connected by its plasma outlet to the process chamber at said remote end.

22. A device according to claim 14, characterized by a work piece holder for the work piece, the work piece holder arranged to move the work piece in the process chamber.

23. A device for reactive magnetron sputtering comprising
a plasma source for generating a plasma flow and having an anode, a cathode and a plasma outlet for the plasma flow,
a process chamber connected to the plasma source at the plasma outlet for receiving plasma, the process chamber arranged to contain a work piece to be coated with material,
characterized in that the plasma source includes filter plates having getter/sorption surfaces for gettering/adsorbing reactive gas ions flowing towards the cathode and neutral particles sputtered from the cathode, the filter plates placed between the cathode and the plasma outlet.

24. A device according to claim 23, characterized in that the sorption filter plates have cylindrical shapes and are located in such a way that axes of the cylinder shapes coincide with an axis of the anode and the cylinder shapes are similar to the shape of the cathode or the sorption filter plates include two sets of flat sorption filter plates crossing each other.

25. A device for reactive magnetron sputtering comprising
a plasma source for generating a plasma flow,
a process chamber connected to the plasma source at the plasma outlet for receiving plasma, the process chamber arranged to contain a work piece to be coated with material,
characterized in that the inlets for a sputtering gas and for a reactive or processing gas to be ionized both are connected directly to the process chamber.
